(19) United States
(12) Patent Application Publication
(10) Pub. No.: US 2025/0031525 A1
(43) Pub. Date: Jan. 23, 2025

(54) DISPLAY DEVICE AND METHOD OF FABRICATING THE SAME

(71) Applicant: Samsung Display Co., Ltd., Yongin-Si (KR)

(72) Inventors: Ji Yoon KIM, Yongin-si (KR); Yool Guk KIM, Yongin-si (KR); Hyeon Sik KIM, Yongin-si (KR); Sang Ho LEE, Yongin-si (KR); Hee Woon IM, Yongin-si (KR)

(21) Appl. No.: 18/616,215

(22) Filed: Mar. 26, 2024

(30) Foreign Application Priority Data
Jul. 21, 2023 (KR) 10-2023-0095273

(51) Int. Cl. H10K 59/122; H10K 59/12

(52) U.S. Cl. CPC H10K 59/122; H10K 59/1201

(57) ABSTRACT

A display device and a method of fabricating the same are provided. The display device comprises a substrate, a transistor disposed on the substrate, a via layer disposed over the transistor and including a contact hole extending to the transistor, a pixel electrode disposed on the via layer and connected to the transistor through the contact hole, a first bank layer disposed on the pixel electrode and extending in a first direction, and a second bank layer extended in a second direction crossing the first direction, a light emitting layer disposed on the pixel electrode, and a common electrode disposed on the light emitting layer, wherein the second bank layer comprises a first region that does not overlap the contact hole and a second region that overlaps the contact hole, and wherein a width of the second region is greater than a width of the first region.

This application claims priority from Korean Patent Application No. 10-2023-0095273 filed on Jul. 21, 2023 in the Korean Intellectual Property Office, the disclosure of which is incorporated herein by reference in its entirety.

### BACKGROUND

### 1. Field of the Disclosure

The present disclosure relates to a display device, and a method of fabricating the same.

### 2. Description of the Related Art

As the information-oriented society evolves, demands for display devices are ever increasing. For example, display devices are employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two electrodes with a light emitting layer interposed between them. Electrons and holes supplied from the two electrodes are recombined in the light emitting layer to generate excitons, and the generated excitons transition from the excited state to the ground state so that light can be emitted.

An organic light-emitting display device including organic light-emitting elements requires no separate light source such as a backlight unit, and thus it consumes less power and can be made light and thin, as well as exhibiting desirable characteristics such as wide viewing angle, high luminance and contrast, and fast response speed. Accordingly, an organic light-emitting display device is attracting attention as the next generation display device.

### SUMMARY

Aspects of the present disclosure provide a display device that can suppress reflection of external light, and a method of fabricating a display device.

It should be noted that objects of the present disclosure are not limited to the above-mentioned object; and other objects of the present disclosure will be apparent to those skilled in the art from the following descriptions.

According to an aspect of the present disclosure, a display device comprises a substrate, a transistor disposed on the substrate, a via layer disposed over the transistor and including a contact hole extending to the transistor, a pixel electrode disposed on the via layer and connected to the transistor through the contact hole, a first bank layer disposed on the pixel electrode and extending in a first direction, and a second bank layer extending in a second direction crossing the first direction, a light emitting layer disposed on the pixel electrode, and a common electrode disposed on the light emitting layer, wherein the second bank layer comprises a first region that does not overlap the contact hole and a second region that overlaps the contact hole, and wherein a width of the second region is greater than a width of the first region.

In an embodiment, the second region of the second bank layer overlaps with the first bank layer.

In an embodiment, a distance from the contact hole to an edge of the second region is equal to or greater than 5 μm.

In an embodiment, a thickness of the second bank layer is greater than a thickness of the first bank layer.

In an embodiment, an angle between one side of the first region and one side of the second region in contact with the one side of the first region is 90 degrees.

In an embodiment, an angle 1 between one side of the first region and one side of the second region in contact with the one side of the first region is greater than 90 degrees.

In an embodiment, the second bank layer comprises a light-blocking material.

In an embodiment, the first bank layer has a thickness of 0.1 to 0.5 μm.

In an embodiment, the second bank layer has a thickness of 1 to 10 μm.

In an embodiment, the first bank layer has a water contact angle of greater than zero degrees and less than 90 degrees.

In an embodiment, the second bank layer has a water contact angle of greater than 90 degrees and less than 180 degrees.

According to an aspect of the present disclosure, a display device comprises a substrate, a transistor disposed on the substrate, a via layer disposed over the transistor and having a contact hole exposing the transistor, a pixel electrode disposed on the via layer and connected to the transistor through the contact hole, a bank layer disposed on the pixel electrode, a light emitting layer disposed on the pixel electrode, and a common electrode disposed on the light emitting layer, wherein the bank layer comprises a first bank portion that does not overlap the contact hole and a second bank portion that overlaps the contact hole, and wherein a width of the second bank portion is greater than a width of the first bank portion.

In an embodiment, a thickness of the second bank portion is greater than a thickness of the first bank portion.

In an embodiment, the bank layer comprises a light-blocking material.

In an embodiment, the bank layer has a water contact angle of greater than 90 degrees and less than 180 degrees.

In an embodiment, the first bank portion has a thickness of 0.1 to 0.5 μm.

In an embodiment, the second bank portion has a thickness of 1 to 10 μm.

In an embodiment, the first bank portion and the second bank portion are formed as one body.

According to an aspect of the present disclosure, a method of fabricating a display device, the method comprises forming a transistor and a via layer on the substrate, etching the via layer to form a contact hole exposing the transistor, forming a pixel electrode connected to the transistor through the contact hole on the via layer, applying a bank material layer on the pixel electrode and using a mask to form a bank layer comprising a first bank portion that does not overlap the contact hole and a second bank portion that overlaps the contact hole, forming a light emitting layer on the pixel electrode, and forming a common electrode on the light emitting layer, wherein a width of the second bank portion is greater than a width of the first bank portion.

In an embodiment, the mask comprises a light-blocking portion, a transmissive portion and a translucent portion, and wherein a portion of the bank material layer in line with the transmissive portion is formed as the second bank portion, while a portion of the bank material layer in line with the translucent portion is formed as the second bank portion.

According to an embodiment of the present disclosure, second bank layers or second bank portions are disposed such that they overlap contact holes in a display device, so that it is possible to prevent lights incident from the outside from being reflected by pixel electrodes disposed in the contact holes.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view schematically showing a display device according to an embodiment of the present disclosure.

FIG. 2 is a cross-sectional view schematically showing a display device according to an embodiment.

FIG. 3 is a plan view schematically showing a circuit layer of a display device according to an embodiment of the present disclosure.

FIG. 4 is an equivalent circuit diagram of a sub-pixel of a display device according to an embodiment of the present disclosure.

FIG. 5 is a cross-sectional view showing a display device according to an embodiment of the present disclosure.

FIG. 6 is a plan view showing a layout of pixels of a display device according to an embodiment of the present disclosure.

FIG. 7 is a plan view showing a first bank of a display device according to an embodiment.

FIG. 8 is a plan view showing a second bank of the display device according to the embodiment.

FIG. 9 is a cross-sectional view taken along line Q1-Q1′ of FIG. 6.

FIG. 10 is a cross-sectional view taken along line Q2-Q2′ of FIG. 6.

FIG. 11 is a cross-sectional view taken along line Q3-Q3′ of FIG. 6.

FIG. 12 is a plan view schematically showing a contact hole and a second bank layer according to an embodiment.

FIG. 13 is a plan view schematically showing a contact hole and a second bank layer according to another embodiment.

FIG. 14 is a plan view schematically showing a contact hole and a second bank layer according to yet another embodiment.

FIGS. 15, 16, 17, 18, and 19 are cross-sectional views showing processing steps of a method of fabricating a display device according to an embodiment of the present disclosure.

FIG. 20 is a plan view showing a layout of pixels of a display device according to an embodiment of the present disclosure.

FIG. 21 is a plan view showing a kb layer of the display device according to the embodiment of the present disclosure.

FIG. 22 is a cross-sectional view taken along line Q4-Q4′ of FIG. 20.

FIG. 23 is a cross-sectional view taken along line Q5-Q5′ of FIG. 20.

FIGS. 24 and 25 are cross-sectional views showing processing steps of a method of fabricating a display device according to an embodiment of the present disclosure.

### DETAILED DESCRIPTION OF THE EMBODIMENTS

The present inventive concept will now be described more fully hereinafter with reference to the accompanying drawings, in which embodiments of the inventive concept are shown. This inventive concept may, however, be embodied in different forms and should not be construed as limited to the embodiments set forth herein. Rather, these embodiments are provided so that this disclosure will be thorough and complete, and will filly convey the scope of the invention to those skilled in the art.

It will be understood that when a first layer is referred to as being “on” a second layer or substrate, the first layer can be directly on the second layer or substrate, or intervening layers may be present. The same reference numbers indicate the same components throughout the specification.

It will be understood that, although ordinal terms “first,” “second,” etc. may be used herein to describe various elements, these elements should not be limited to any order by these terms. These terms are used to distinguish one element from another element, and may be interchangeable. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

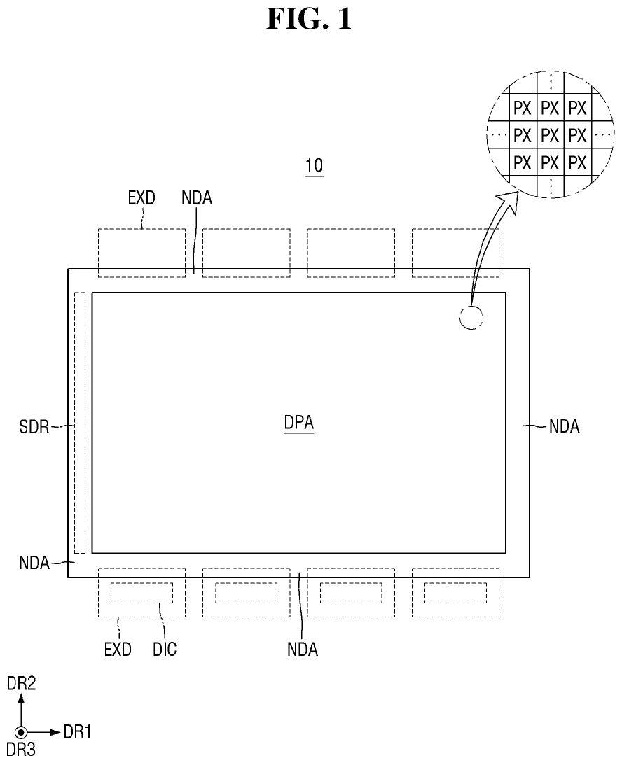

FIG. 1 is a plan view schematically showing a display device according to an embodiment of the present disclosure.

Referring to FIG. 1, a display device 10 according to an embodiment of the present disclosure may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc. In the following description, a television is described as an example of the display device. TV may have a high resolution or ultra high resolution such as HD, UHD, 4K and 8K.

The display device 10 according to the embodiments may be variously classified by the way in which images are displayed. Examples of the classification of display devices may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED) and a cathode ray display device (CRT), a liquid-crystal display device (LCD), an electrophoretic display device (EPD), etc. In the following description, an organic light-emitting display device and an inorganic light-emitting display device will be described as an example of the display device, and the organic light-emitting display device and the inorganic light-emitting display device will be simply referred to as a display device unless it is necessary to distinguish between them. It is, however, to be understood that the embodiments of the present disclosure are not limited thereto, and any other display device listed above or well known in the art may be employed without departing from the scope of the present disclosure.

A first direction DR1, a second direction DR2 and a third direction DR3 are defined in the drawings. The display device 10 according to the embodiments of the present disclosure will be described with reference to the drawings. The first direction DR1 may be perpendicular to the second direction DR2. The third direction DR3 may be perpendicular to the plane defined by the first direction DR1 and the second direction DR2. The third direction DR3 may be perpendicular to each of the first direction DR1 and the second direction DR2. In the following description of the display devices 10 according to the embodiments of the present disclosure, the third direction DR3 refers to the thickness direction of the display device 10.

The display device 10 may have a rectangular shape including longer sides in the first direction DR1 and shorter sides in the second direction DR2 when viewed from the top. Although the corners where the longer sides and the shorter sides of the display device 10 meet may form a right angle, this is merely illustrative. The display device 1 may have rounded corners. The shape of the display device 10 when viewed from the top is not limited to that shown. The display device 10 may have other shapes such as a square, a rectangle with rounded corners (vertices), other polygons and a circle.

A display surface may be located on one side of the display device 10 in the third direction DR3, i.e., the thickness direction. In the following description, the upper side of the display device 10 refers to the surface where images are displayed, and the upper surface of the display device 10 refers to the surface facing the positive third direction DR3, unless specifically stated otherwise. A “positive third direction DR3” refers to the direction in which the arrow points for the DR3 axis in the coordinates shown. A “negative third direction DR3” refers to the direction that is opposite the direction in which the arrow points for the DR3 axis in the coordinates shown. The lower portion refers to the portion that is to the negative third direction DR3, and likewise the lower surface refers to a surface facing the negative third direction DR3. As used herein, the terms “left,” “right,” “upper” and “lower” sides refer to relative positions when the display device 10 is viewed from the top. For example, the right side refers to one side in the first direction DR1, the left side refers to the other side in the first direction DR1, the upper side refers to one side in the second direction DR2, and the lower side refers to the other side in the second direction DR2.

The display device 10 may include a display area DPA and a non-display area NDA. The display area DPA may refer to an active area where images are displayed, while the non-display area NDA may refer to an inactive area where no image is displayed.

The shape of the display area DPA may be similar to the general shape of the display device 10. For example, the display area DPA may have a rectangular shape when viewed from the top. The display area DPA may generally occupy the center of the display device 10.

The display area DPA may include a plurality of pixels PX. The plurality of pixels PX may be arranged in a matrix. The shape of each of the pixels PX may be rectangular or square when viewed from the top. It is, however, to be understood that the present disclosure is not limited thereto. The shape of each of the pixels PX may have a diamond shape having the sides inclined with respect to one direction. The pixels PX may be arranged in stripes or the PenTile™ pattern alternately.

The non-display area NDA may be disposed around the display area DPA. The non-display area NDA may surround the display area DPA entirely or partially. The display area DPA may have a rectangular shape, and the non-display area NDA may be adjacent to the four sides of the display area DPA. The non-display area NDA may form the bezel of the display device 10.

In the non-display areas NDA, a driver circuit or a driving element for driving the display area DPA may be disposed. The non-display area NDA may include first to fourth non-display area NDA1, NDA2, NDA3 and NDA4. According to an embodiment of the present disclosure, a pad area is disposed on the display substrate of the display device 10 in a first non-display area NDA1 disposed adjacent to a first longer side (the lower side in FIG. 1) of the display device 10 and a second non-display area NDA2 adjacent to a second longer side (the upper side in FIG. 1) of the display device 1. An external device EXD may be mounted on a pad electrode of the pad area. Examples of the external devices EXD may include a connection layer, a printed circuit board, a driver chip DIC, a connector, a line connection layer, etc. A scan driver SDR formed directly on the display substrate of the display device 10 may be disposed in the third non-display area NDA3 disposed adjacent to a first shorter side of the display device 1 (the left side in FIG. 1).

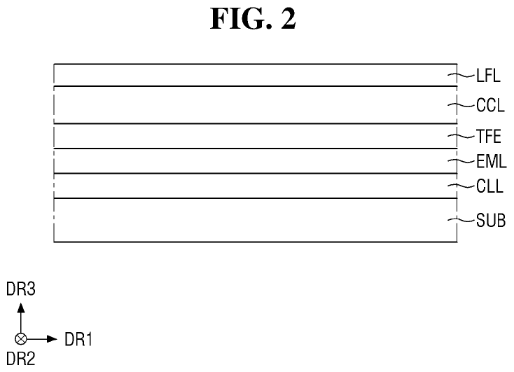

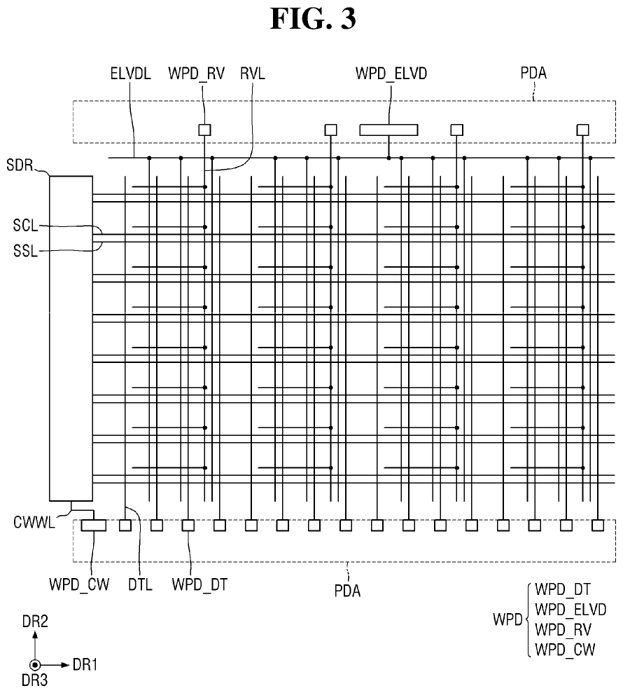

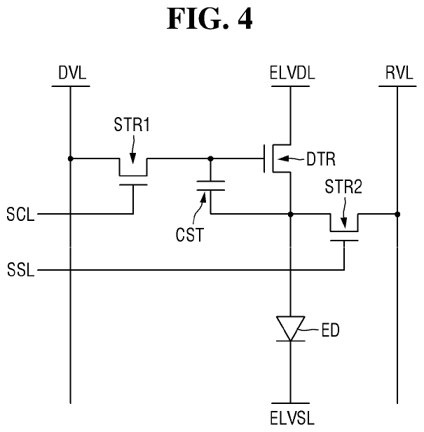

FIG. 2 is a cross-sectional view schematically showing a display device according to an embodiment. FIG. 3 is a plan view schematically showing a circuit layer of a display device according to an embodiment of the present disclosure. FIG. 4 is an equivalent circuit diagram of a sub-pixel of a display device according to an embodiment of the present disclosure.

Referring to FIG. 2, the display device 10 according to the embodiment of the present disclosure may include a substrate SUB, a circuit layer CIL disposed on the substrate SUB, an emission material layer EML disposed on the circuit layer CIL, an encapsulation layer TFE disposed on the emission material layer EML, a color conversion layer CCL disposed on the encapsulation layer TFE, and an optical functional layer LFL disposed on the color conversion layer CCL.

Referring to FIG. 3, the circuit layer CIL may include a plurality of lines on the substrate SUB. The plurality of lines may include a scan line SCL, a sensing signal line SSL, a data line DTL, a reference voltage line RVL, a first supply voltage line ELVDL, etc.

The scan line SCL and the sensing signal line SSL may be extended in the first direction DR1. The scan line SCL and the sensing signal line SSL may be connected to the scan driver SDR. The scan driver SDR may include a driver circuit formed of the circuit layer CIL. The scan driver SDR may be disposed in the third non-display area NDA3 on the substrate SUB, but the present disclosure is not limited thereto. The scan driver SDR may be disposed in a fourth non-display area NDA4 or both the third non-display area NDA3 and the fourth non-display area NDA4. The scan driver SDR may be connected to a signal connection line CWWL. At least one end of the signal connection line CWWL may form a pad WPD_CW on the first non-display area NDA1 and/or the second non-display area NDA2 and may be connected to an external device EXD (scc FIG. 1).

The data line DTL and the reference voltage line RVL may be extended in the second direction DR2 crossing the first direction DR1. A first supply voltage line ELVDL may include a portion extending in the second direction DR2. The first supply voltage line ELVDL may further include a portion extending in the first direction DR1. The first supply voltage line ELVDL may have, but is not limited to, a mesh structure.

The wire pads WPD may be disposed at at least one end of the data line DTL, the reference voltage line RVL, and the first supply voltage line ELVDL. The wire pads WPD may be disposed in the pad area PDA of the first non-display area NDA1. According to an embodiment of the present disclosure, a wire pad WPD_DT of the data line DTL (hereinafter, referred to as a data pad) may be disposed in the pad area PDA of the first non-display area NDA1. A wire pad WPD_RV of the reference voltage line RVL (hereinafter referred to as a reference voltage pad) and a wire pad WPD_ELVD of the first supply voltage line ELVDL (hereinafter referred to as a first supply voltage pad) may be disposed in the pad area PDA of the second non-display area NDA2. As another example, the data pad WPD_DT, the reference voltage pad WPD_RV and the first supply voltage pad WPD_ELVD may all be disposed in the same area, e.g., the first non-display area NDA1. As described above, the external devices EXD (see FIG. 1) may be mounted on the wire pad WPD. The external devices EXD may be mounted on the wire pads WPD by an anisotropic conductive layer, ultrasonic bonding, etc.

Each of the pixels PX on the substrate SUB includes a plurality of sub-pixels, and each of the plurality of sub-pixels includes a pixel driver circuit. The above-described lines may be extended around each of the pixels PX or the sub-pixels to apply a driving signal to the pixel driver circuit. The pixel driver circuit may include transistors and a capacitor. The numbers of transistors and capacitors of each pixel driver circuit may be changed in a variety of ways. In the following description, the pixel driver circuit having a 3T1C structure including three transistors and one capacitor will be described as an example. It is, however, to be understood that the present disclosure is not limited thereto. A variety of modifications having other structures such as a 2T1C structure, a 7T1C structure and a 6T1C structure may be employed.

FIG. 4 is an equivalent circuit diagram of a sub-pixel of a display device according to an embodiment of the present disclosure.

Referring to FIG. 4, each of the pixels PX of the display device according to the embodiment includes a plurality of sub-pixels, and each of the sub-pixels includes three transistors DTR, STR1 and STR2 and one storage capacitor CST in addition to the light-emitting element ED.

The light-emitting element ED emits light with brightness that is in proportion to the current supplied through the driving transistor DTR. The light-emitting element ED may be implemented as an organic light-emitting diode, a micro light-emitting diode, a nano light-emitting diode, etc.

The first electrode (i.e., the pixel electrode) of the light-emitting element ED may be connected to the source electrode of the driving transistor DTR, and the second electrode (i.e., the common electrode) thereof may be connected to a second supply voltage line ELVSL, from which a low-level voltage (second supply voltage) is applied, lower than a high-level voltage (first supply voltage) of a first supply voltage line ELVDL.

The driving transistor DTR adjusts a current flowing from the first supply voltage line ELVDL from which the first supply voltage is applied to the light-emitting element ED according to the voltage difference between the gate electrode and the source electrode. The gate electrode of the driving transistor DTR may be connected to a first source/drain electrode of a switching transistor STR1, the source electrode thereof may be connected to the first electrode of the light-emitting element ED, and the drain electrode thereof may be connected to the first supply voltage line ELVDL from which the first supply voltage is applied.

The switching transistor STR1 is turned on by a scan signal of a scan line SCL to connect a data line DTL with the gate electrode of the driving transistor DTR. A gate electrode of the switching transistor STR1 may be connected to the scan line SCL, the first source/drain electrode may be connected to the gate electrode of the driving transistor DTR1, and a second source/drain electrode thereof may be connected to the data line DTL.

The sensing transistor STR2 may be turned on by a sensing signal of a sensing signal line SSL to connect a reference voltage line RVL to the source electrode of the driving transistor DTR. A gate electrode of the sensing transistor STR2 may be connected to the sensing signal line SSL, the first source/drain electrode thereof may be connected to the reference voltage line RVL, and the second source/drain electrode thereof may be connected to the source electrode of the driving transistor DTR.

According to an embodiment of the present disclosure, the first source/drain electrode of each of the switching and sensing transistors STR1 and STR2 may be a source electrode while the second source/drain electrode thereof may be a drain electrode. It is, however, to be understood that the present disclosure is not limited thereto. The first source/drain electrode of each of the switching and sensing transistors STR1 and STR2 may be a drain electrode while the second source/drain electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR, the switching transistor STR1 and the sensing transistor STR2 may be implemented as thin-film transistors. Although the driving transistor DTR, the switching transistor STR1 and the sensing transistor STR2 are implemented as n-type metal oxide semiconductor field effect transistors (MOSFET) in the example shown in FIG. 4, it is to be noted that the present disclosure is not limited thereto. Specifically, the driving transistor DTR and the switching transistor STR1 and the sensing transistor STR2 may be implemented as p-type MOSFETs, or some of them may be implemented as n-type MOSFETs while the others may be implemented as p-type MOSFETs.

Hereinafter, the structure of the display area DPA of the display device 10 will be described in more detail.

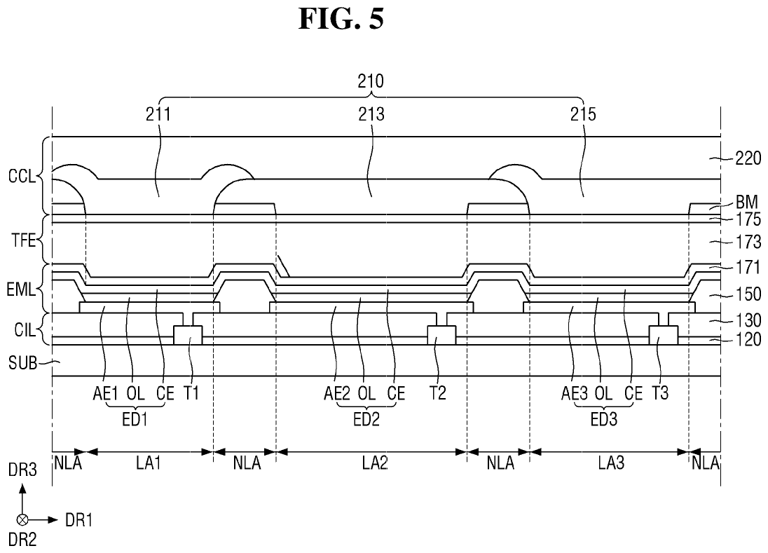

FIG. 5 is a cross-sectional view showing a display device according to an embodiment of the present disclosure.

Referring to FIG. 5, the display device 10 may include the substrate SUB, the circuit layer CIL disposed on the substrate SUB, the emission material layer EML disposed on the circuit layer CIL, the encapsulation layer TFE disposed on the emission material layer EML, and the color conversion layer CCL disposed on the encapsulation layer TFE.

The substrate SUB may be an insulating substrate. The substrate SUB may include a transparent material. For example, the substrate SUB may include a transparent insulating material such as glass and quartz. The substrate SUB may be a rigid substrate. However, the substrate SUB is not limited to those described above. The substrate SUB may include a plastic such as polyimide, or may be flexible so that it can be curved, bent, folded or rolled. A plurality of emission areas LA1, LA2 and LA3 and a non-emission area NLA may be defined on the substrate SUB.

The circuit layer CIL may be disposed on the substrate SUB. The circuit layer CIL may include switching elements T1, T2 and T3. According to the embodiment of the present disclosure, the first switching element T1 may be located in the first emission area LA1 of the substrate SUB, the second switching element T2 may be located in the second emission area LA2, and the third switching element T3 may be located in the third emission area LA3. It is, however, to be understood that the present disclosure is not limited thereto. In other embodiments, at least one of the first switching device T1, the second switching device T2 and the third switching device T3 may be located in the non-emission area NLA.

According to an embodiment of the present disclosure, each of the first switching element T1, the second switching element T2 and the third switching element T3 may be a thin-film transistor including amorphous silicon, polysilicon, or an oxide semiconductor. Although not shown in the drawings, a plurality of signal lines described above with reference to FIG. 3 (for example, gate lines, data lines, power lines, etc.) may be further disposed on the substrate SUB. In addition, the switching elements T1, T2 and T3 may include a first insulating layer 120. For example, the first insulating layer 120 may be a gate insulator or an interlayer dielectric layer of a thin-film transistor. The gate insulator or the interlayer dielectric layer may be a single layer including one of silicon oxide (SiOx), silicon nitride oxide (SiOxNy), and silicon nitride (SiNx), or a multi-layer structure that includes layers of the above materials.

A second insulating layer 130 may be disposed over the first switching element T1, the second switching element T2 and the third switching element T3. According to an embodiment of the present disclosure, the second insulating layer 130 may be a planarization layer. According to an embodiment of the present disclosure, the second insulating layer 130 may be formed as an organic layer. For example, the second insulating layer 130 may include an acrylic resin, an epoxy resin, an imide resin, an ester resin, etc. According to an embodiment of the present disclosure, the second insulating layer 130 may include a positive photoresist or a negative photoresist.

The emission material layer EML may be disposed on the second insulating layer 130. The emission material layer EML may include pixel electrodes AE1, AE2 and AE3, light emitting layers OL, and a common electrode CE. In addition, the emission material layer EML may further include a bank layer 150.

The pixel electrodes AE1, AE2 and AE3 may be disposed on the second insulating layer 130. The pixel electrodes AE1, AE2 and AE3 may include a first pixel electrode AE1, a second pixel electrode AE2, and a third pixel electrode AE3. The first pixel electrode AE1 may be disposed in the first emission area LA1 and may be extended to the non-emission area NLA at least partially. The second pixel electrode AE2 may be disposed in the second emission area LA2 and may be extended to the non-emission area NLA at least partially. The third pixel electrode AE3 may be disposed in the third emission area LA3 and may be extended to the non-emission area NLA at least partially. The first pixel electrode AE1 may be connected to the first switching element T1 through the second insulating layer 130, the second pixel electrode AE2 may be connected to the second switching element T2 through the second insulating layer 130, and the third pixel electrode AE3 may be connected to the third switching element T3 through the second insulating layer 130.

According to an embodiment of the present disclosure, the widths or areas of the first pixel electrode AE1, the second pixel electrode AE2 and the third pixel electrode AE3 may be different from one another. For example, the width of the first pixel electrode AE1 may be smaller than the width of the second pixel electrode AE2, and the width of the third pixel electrode AE3 may be smaller than the width of the second pixel electrode AE2 and may be larger than the width of the first electrode AE1. Alternatively, the width of the first pixel electrode AE1 may be smaller than the width of the second pixel electrode AE2, and the width of the third pixel electrode AE3 may be smaller than the width of the second pixel electrode AE2 and may be larger than the width of the first electrode AE1. Alternatively, the width of the first pixel electrode AE1 may be smaller than the width of the second pixel electrode AE2, and the width of the third pixel electrode AE3 may be larger than the width of the second pixel electrode AE2 and the width of the first electrode AE1. It is, however, to be understood that the present disclosure is not limited to the above-described embodiment. According to another embodiment of the present disclosure, the widths or areas of the first pixel electrode AE1, the second pixel electrode AE2 and the third pixel electrode AE3 may be substantially all equal.

The first pixel electrode AE1, the second pixel electrode AE2 and the third pixel electrode AE3 may be reflective electrodes. The first pixel electrode AE1, the second pixel electrode AE2 and the third pixel electrode AE3 may have a stack structure of a material layer having a high work function such as indium-tin-oxide (ITO), indium-zinc-oxide (IZO), zinc oxide (ZnO) and indium oxide (In203), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. A material layer having a higher work function may be disposed on a higher layer than a reflective material layer so that it may be closer to the light emitting layers OL. The first pixel electrode AE1, the second pixel electrode AE2 and the third pixel electrode AE3 may have, but is not limited to, a multilayer structure of ITO/Mg, ITO/MgF, ITO/Ag, and ITO/Ag/ITO.

The bank layer 150 may be located on the first pixel electrode AE1, the second pixel electrode AE2, and the third pixel electrode AE3. The bank layer 150 may include an opening extending to the first pixel electrode AE1, an opening extending to the second pixel electrode AE2 and an opening extending to the third pixel electrode AE3, and may define the first emission area LA1, the second emission area LA2, the third emission area LA3 and the non-emission area NLA. Specifically, an area of the first pixel electrode AE1 that is not covered by the bank BNL and is exposed may be the first emission area LA1. An area of the second pixel electrode AE2 that is not covered by the bank layer 150 and is exposed may be the second emission area LA2. An area of the third pixel electrode AE3 that is not covered by the bank layer 150 and is exposed may be the third emission area LA3. The other area where the bank layer 150 is located may be the non-emission area NLA. The bank layer 150 may overlap a light-blocking layer BM of the color conversion layer CCL, which will be described later.

The light emitting layers OL may be disposed on the first pixel electrode AE1, the second pixel electrode AE2, and the third pixel electrode AE3. In an embodiment where the display device 10 is an organic light-emitting display device, the light emitting layers OL may include an organic layer containing an organic material. The organic layer includes an organic, light emitting layer and may further include at least one of: a hole injection layer, a hole transport layer, an electronic transport layer and an electron injection layer as an auxiliary layer in some implementations in order to facilitate light emission. According to an embodiment of the present disclosure, the light emitting layers OL may have a tandem structure including a plurality of organic light emitting layers overlapping one another in the thickness direction and a charge generation layer disposed therebetween. The organic light emitting layers overlapping one another may emit either light of the same wavelength or lights of different wavelengths.

According to an embodiment of the present disclosure, the light emitting layers OL may be disposed in each of the plurality of emission areas LA1, LA2 and LA3, respectively. The wavelengths of lights emitted from the light emitting layers OL may be the same. For example, the light emitting layers OL may emit blue light or ultraviolet light from the plurality of emission areas LA1, LA2 and LA3.

The common electrode CE may be disposed on the light emitting layers OL. According to an embodiment of the present disclosure, the common electrode CE may be translucent or transmissive. If the common electrode CE is translucent, the common electrode CE may include Ag, Mg, Cu, Al, Pt, Pd, Au, Ni, Nd, Ir, Cr, Li, Ca, LiF/Ca, LiF/Al, Mo, Ti or a compound or a mixture thereof, e.g., a mixture of Ag and Mg. Further, if the thickness of the common electrode CE ranges from several tens to several hundred angstroms, the common electrode CE may be translucent.

When the common electrode CE is transmissive, the common electrode CE may include a transparent conductive oxide (TCO). For example, the common electrode CE may be formed of tungsten oxide (WxOy), titanium oxide (TiO2), indium tin oxide (ITO), indium zinc oxide (IZO), zinc oxide (ZnO), indium tin zinc oxide MgO (magnesium oxide), etc.

The first pixel electrode AE1, the light emitting layer OL and the common electrode CE may form a first light-emitting element ED1, the second pixel electrode AE2, the light emitting layer OL and the common electrode CE may form a second light-emitting element ED2, and the third pixel electrode AE3, the light emitting layer OL and the common electrode CE may form a third light-emitting element ED3. Each of the first light-emitting element ED1, the second light-emitting element ED2 and the third light-emitting element ED3 may emit a source light. The source light may be provided to the color conversion layer CCL. The first light-emitting element ED1, the second light-emitting element ED2 and the third light-emitting element ED3 may be organic light-emitting diodes.

The encapsulation layer TFE may be disposed on the common electrode CE. The encapsulation layer TFE may be located commonly across the first emission area LA1, the second emission area LA2, the third emission area LA3, and the non-emission area NLA. According to an embodiment of the present disclosure, the encapsulation layer TFE may directly cover the common electrode CE.

According to an embodiment of the present disclosure, the encapsulation layer TFE may include a first inorganic encapsulation layer 171, an organic encapsulation layer 173 and a second inorganic encapsulation layer 175 sequentially stacked on the common electrode CE.

Each of the first inorganic encapsulation layer 171 and the second inorganic encapsulation layer 175 may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and the like. The organic encapsulation layer 173 may include an acrylic resin, a methacrylate-based resin, polyisoprene, a vinyl resin, an epoxy resin, an urethane resin, a cellulose resin and a perylene resin. It is to be noted that the structure of the encapsulation layer TFE is not limited to the above example. The stack structure of the encapsulation layer TFE may be altered in a variety of ways.

The color conversion layer CCL may be disposed on the encapsulation layer TFE. The color conversion layer CCL may include the light-blocking layer BM and a color filter layer 210.

The light-blocking layer BM may be disposed on the encapsulation layer TFE. The light-blocking layer BM may be disposed such that it overlaps the bank layer 150 of the emission material layer EML. The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking layer BM can prevent visible light from penetrating and mixing colors between the first to third emission areas LA1, LA2 and LA3 to improve the color gamut of the display device 10.

The color filter layer 210 may be disposed on the light-blocking layer BM and the encapsulation layer TFE. The color filter layer 210 may include a first color filter CF1, a second color filter CF2, and a third color filter CF3.

The first color filter 211 may be positioned on the encapsulation layer TFE and may overlap with the first emission area LA1. In addition, the first color filter 211 may overlap with the first light-emitting element ED1.

The first color filter 211 may selectively transmit light of a first color (e.g., blue light) and may block or absorb light of a second color (e.g., red light) and light of a third color (e.g., green light). According to an embodiment of the present disclosure, the first color filter 211 may be a blue color filter and may include a blue colorant such as a blue dye and a blue pigment. As used herein, a colorant encompasses a dye as well as a pigment.

The second color filter 213 may overlap with the second emission area LA2 and may overlap with the second light-emitting element ED2. According to an embodiment of the present disclosure, one side of the second color filter 213 may overlap with the non-emission area NLA and overlap with a portion of the adjacent first color filter 211. The opposite side of the second color filter 213 may overlap with the non-emission area NLA and overlap with a portion of the third color filter 215.

The second color filter 213 may block or absorb the light of the first color (e.g., blue light) and the light of the third color (e.g., green light). The second color filter 213 may selectively transmit the light of the second color (e.g., red light). For example, the second color filter 213 may be a red color filter and may include a red colorant such as a red dye and a red pigment.

The third color filter 215 may overlap with the third emission area LA3 and may overlap with the third light-emitting element ED3. According to an embodiment of the present disclosure, one side of the third color filter 215 may overlap with the non-emission area NLA and overlap with a portion of the adjacent second color filter 213. In addition, the opposite side of the third color filter 215 may overlap with the non-emission area NLA and overlap with a portion of the adjacent first color filter 211.

The third color filter 215 may block or absorb the light of the first color and the light of the second color. The third color filter 215 may selectively transmit the light of the third color. For example, the third color filter 215 may be a green color filter and may include a green colorant such as a green dye and a green pigment.

The color conversion layer CCL may further include an overcoat layer 220. The overcoat layer 220 may be disposed on the first color filter 211, the second color filter 213 and the third color filter 215 and may provide a flat surface over the level differences.

The overcoat layer 220 may be made of an organic material. The overcoat layer 220 may be a colorless light-transmitting layer having no color in the visible light band. For example, the overcoat layer 220 may include a colorless light-transmitting organic material such as an acryl-based resin.

An anti-reflection layer or an anti-fingerprint layer may be further disposed on the color conversion layer CCL to prevent reflection of external light.

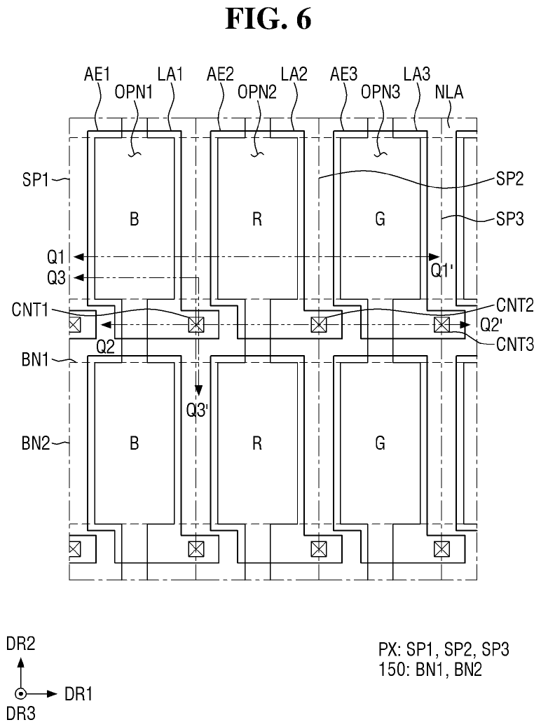

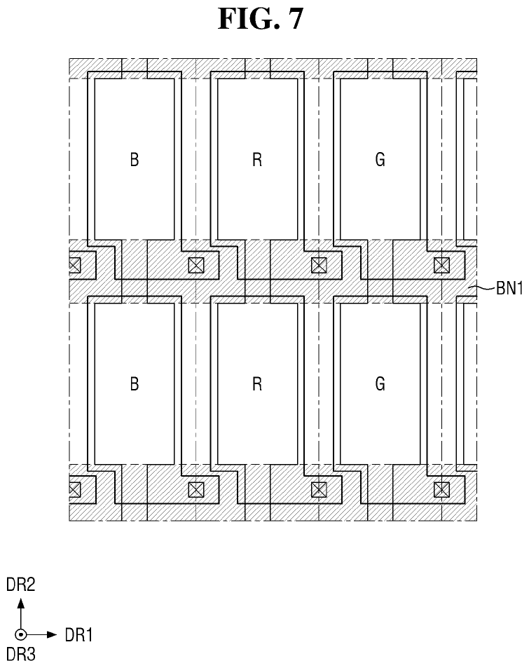

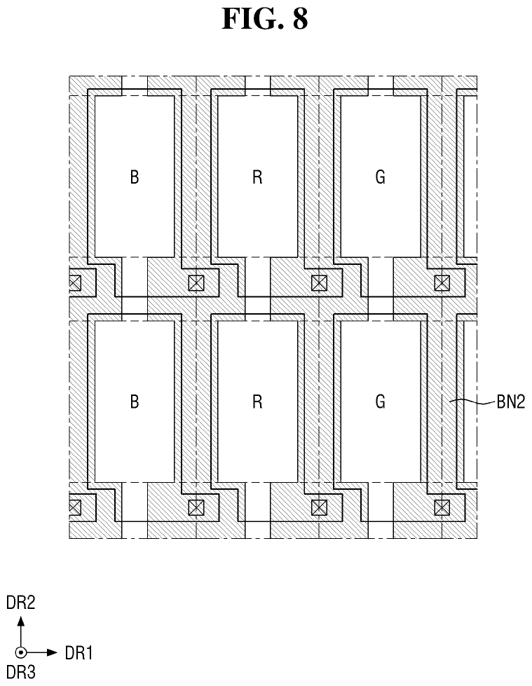

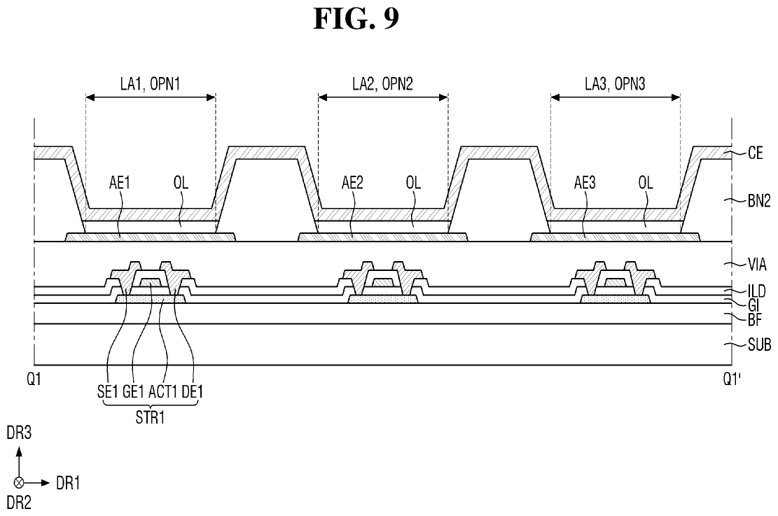

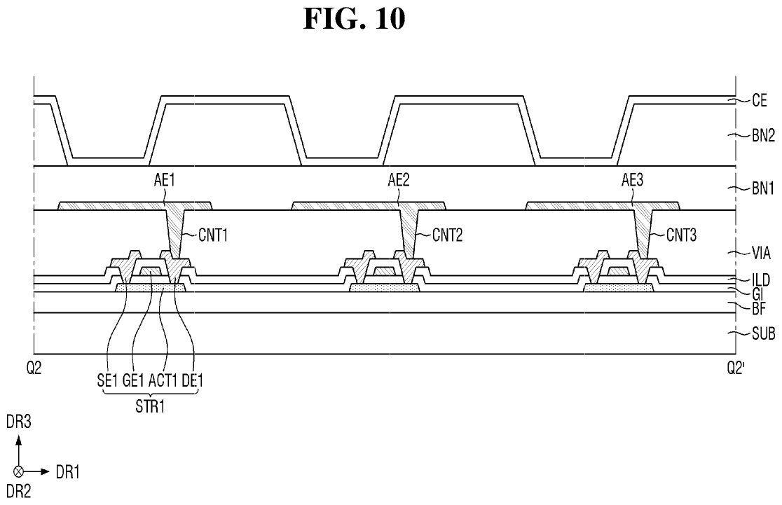

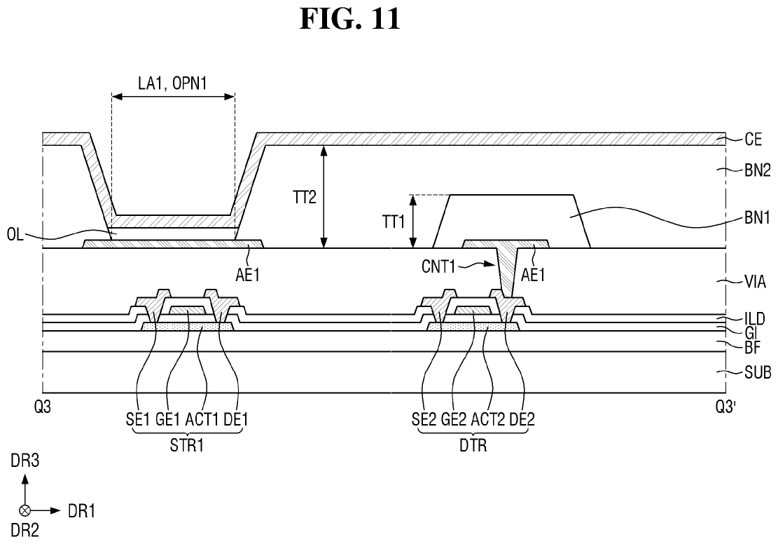

FIG. 6 is a plan view showing a layout of pixels of a display device according to an embodiment of the present disclosure. FIG. 7 is a plan view showing a first bank of a display device according to an embodiment. FIG. 8 is a plan view showing a second bank of the display device according to the embodiment. FIG. 9 is a cross-sectional view taken along line Q1-Q1′ of FIG. 6. FIG. 10 is a cross-sectional view taken along line Q2-Q2′ of FIG. 6. FIG. 11 is a cross-sectional view taken along line Q3-Q3′ of FIG. 6.

Referring to FIGS. 6 to 11, the display area DPA of the display device 10 may include a plurality of pixels PX. Each of the pixels PX refers to a repeating minimum unit for displaying images. The pixels PX each including a plurality of sub-pixels SP1, SP2 and SP3 may be arranged sequentially and repeatedly in rows and columns.

In order to display full-color, each of the pixels PX may include a plurality of sub-pixels SP1, SP2 and SP3, which emit different colors. For example, each of the pixels PX may include a first sub-pixel SPX1 responsible for emitting light of blue color, a second sub-pixel SPX2 responsible for emitting light of red color, and a third sub-pixel SPX3 responsible for emitting light of green color. One first sub-pixel SP1, one second sub-pixel SP2 and one third sub-pixel SP3 may be provided for each of the pixels PX.

Each of the sub-pixels SP1, SP2 and SP3 may include an emission area EMA and a non-emission area NLA around the emission area EMA. The non-emission area NLA may be located between the emission areas of the sub-pixel SP1, SP2 and SP3. For example, areas between the first sub-pixel SP1, the second sub-pixel SP2 and the third sub-pixel SP3 may be the non-emission area NLA.

The sub-pixels SP1, SP2 and SP3 in each of the pixels PX may include emission areas LA1, LA2 and LA3, respectively. For example, the first sub-pixel SP1 may include the first emission area LA1, the second sub-pixel SP2 may include the second emission area LA2, and the third sub-pixel SP3 may include the third emission area LA3. The shapes and sizes of the emission areas LA1, LA2 and LA3 may be the same. It should be understood, however, that the present disclosure is not limited thereto. The shapes and sizes of the emission areas LA1, LA2 and LA3 may be different from one another.

According to an embodiment of the present disclosure, the sub-pixels SP1, SP2 and SP3 may be extended in the second direction DR2. For example, the first sub-pixels SP1 may be extended in the second direction DR2, the second sub-pixels SP2 may be extended in the second direction DR2, and the third sub-pixels SP3 may be extended in the second direction DR2. The first sub-pixel SP1, the second sub-pixel SP2 and the third sub-pixel SP3 may be arranged sequentially and repeatedly in the first direction DR1.

A buffer layer BF may be disposed on the substrate SUB. The buffer layer BF may be disposed throughout the entire surface of the substrate SUB. The buffer layer BF can prevent impurity ions from diffusing and can prevent permeation of moisture. The buffer layer BF may include silicon nitride, silicon oxide, silicon oxynitride, or the like.

A first semiconductor layer ACT1 and a second semiconductor layer ACT2 may be disposed on the buffer layer BF. The first semiconductor layer ACT1 may include a channel of the switching transistor STR1, and the second semiconductor layer ACT2 may include a channel of the driving transistor DTR. The first semiconductor layer ACT1 and the second semiconductor layer ACT2 may include polycrystalline silicon. The polycrystalline silicon may be formed by crystallizing amorphous silicon. When the first semiconductor layer ACT1 and the second semiconductor layer ACT2 are made of polycrystalline silicon, the first semiconductor layer ACT1 and the second semiconductor layer ACT2 can have conductivity by doping the first semiconductor layer ACT1 and the second semiconductor layer ACT2 with ions. Accordingly, the first semiconductor layer ACT1 and the second semiconductor layer ACT2 may include source and drain regions as well as channel regions of the plurality of transistors. The source region and the drain region may be connected to both sides of each channel region.

According to another embodiment, the first semiconductor layer ACT1 and the second semiconductor layer ACT2 may include monocrystalline silicon, low-temperature polycrystalline silicon, amorphous silicon, or an oxide semiconductor. The oxide semiconductor may include, for example, a binary compound (ABx), a ternary compound (ABxCy) and a quaternary compound (ABxCyDz) containing indium, zinc, gallium, tin, titanium, aluminum, hafnium (Hf), zirconium (Zr), magnesium (Mg), etc. According to the embodiment of the present disclosure, the first semiconductor layer ACT1 and the second semiconductor layer ACT2 may include an oxide including indium, tin and titanium (ITZO) or an oxide including indium, gallium and tin (IGZO).

A gate insulator GI may be disposed on the first semiconductor layer ACT1 and the second semiconductor layer ACT2. The gate insulator GI may be generally disposed over the entire surface of the substrate SUB. The gate insulator GI may include a silicon compound, a metal oxide, etc. For example, the gate insulator GI may include silicon oxide, silicon nitride, silicon oxynitride, aluminum oxide, tantalum oxide, hafnium oxide, zirconium oxide, titanium oxide, etc. The gate insulator GI may be made up of a single layer or multiple layers of different materials stacked on one another.

A first gate electrode GE1 and a second gate electrode GE2 may be disposed on the gate insulator GI. The first gate electrode GE1 may overlap with the channel region of the first semiconductor layer ACT1, and the second gate electrode GE2 may overlap with the channel region of the second semiconductor layer ACT2. The first gate electrode GE1 and the second gate electrode GE2 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first gate electrode GE1 and the second gate electrode GE2 may be made up of a single layer or multiple layers.

An interlayer dielectric layer ILD may be disposed over the first gate electrode GE1, the second gate electrode GE2 and the gate insulator GI. The interlayer dielectric layer ILD may be disposed throughout the entire surface of the substrate SUB. The interlayer dielectric layer ILD may include the same material as the above-described gate insulator GI or may include one or more materials selected from the materials listed above as the materials of the gate insulator GI.

A first source electrode SE1, a first drain electrode DE1, a second source electrode SE2 and a second drain electrode DE2 may be disposed on the interlayer dielectric layer ILD. The first source electrode SE1 and the first drain electrode DE1 may be electrically connected to the first semiconductor layer ACT1 through contact holes penetrating through the gate insulator GI and the interlayer dielectric layer ILD. The second source electrode SE2 and the second drain electrode DE2 may be electrically connected to the second semiconductor layer ACT2 through contact holes penetrating through the gate insulator GI and the interlayer dielectric layer ILD.

The first semiconductor layer ACT1, the first gate electrode GE1, the first source electrode SE1 and the first drain electrode DE1 may form the switching transistor STR1. The second semiconductor layer ACT2, the second gate electrode GE2, the second source electrode SE2, and the second drain electrode DE2 may form the driving transistor DTR. It should be understood, however, that the present disclosure is not limited thereto. The first semiconductor layer ACT1, the first gate electrode GE1, the first source electrode SE1, and the first drain electrode DE1 may form a sensing transistor.

The first source electrode SE1, the first drain electrode DE1, the second source electrode SE2 and the second drain electrode DE2 may include at least one metal selected from the group consisting of: aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first source electrode SE1, the first drain electrode DE1, the second source electrode SE2 and the second drain electrode DE2 may be a single layer or a multilayer structure. For example, the first source electrode SE1, the first drain electrode DE1, the second source electrode SE2 and the second drain electrode DE2 may be formed in a stack structure of Ti/Al/Ti, Mo/Al/Mo, Mo/AlGe/Mo, Ti/Cu, etc.

A via layer VIA may be disposed over the first source electrode SE1, the first drain electrode DE1, the second source electrode SE2, and the second drain electrode DE2. The via layer VIA may provide a flat surface over the elements having different heights in the display area DPA. The via layer VIA may include an organic insulating material such as polyacrylate resin, epoxy resin, phenolic resin, polyamide resin, polyimide resin, unsaturated polyesters resin, polyphenylene ether resin, polyphenylene sulfide resin, and benzocyclobutene (BCB).

The pixel electrodes AE1, AE2 and AE3 and the bank layer 150 may be disposed on the via layer VIA. The pixel electrodes AE1, AE2 and AE3 may be connected to the driving transistors therebelow through contact holes CNT1, CNT2 and CNT3. Each of the contact holes CNT1, CNT2 and CNT3 may penetrate through the via layer VIA to expose the second drain electrode DE2 of the driving transistor DTR. For example, the first pixel electrode AE1 may be connected to the second drain electrode DE2 of the driving transistor DTR through the first contact hole CNT1, the second pixel electrode AE2 may be connected to the second drain electrode DE2 of the driving transistor DTR through the second contact hole CNT2, and the third pixel electrode AE3 may be connected to the second drain electrode DE2 of the driving transistor DTR through the third contact hole CNT3. The contact holes CNT1, CNT2 and CNT3 may overlap with pixel electrodes AE1, AE2 and AE3 and may be located in the non-emission area NLA.

The bank layer 150 may be disposed along the boundary of each sub-pixel SP1, SP2 and SP3. The bank layer 150 may be disposed on at least one of the pixel electrodes AE1, AE2 and AE3 and the via layer VIA (see FIG. 4). The bank layer 150 may include openings OPN1, OPN2 and OPN3 exposing the pixel electrodes AE1, AE2 and AE3, respectively. The openings OPN1, OPN2, and OPN3 may include a first opening OPN1 exposing the first pixel electrode AE1, a second opening OPN2 exposing the second pixel electrode AE2, and a third opening OPN3 exposing the third pixel electrode AE3. The non-emission area NLA and the emission areas LA1, LA2 and LA3 may be distinguished from each other by the bank layer 150. The bank layer 150 will be described in more detail later.

An emission layer OL may be disposed on each of the pixel electrodes AE1, AE2 and AE3 exposed by the bank layer 150. The light emitting layer OL may include an organic material layer. The organic material layer of the light emitting layer OL may include an organic emission layer and may further include a hole injecting/transporting layer and/or an electron injecting/transporting layer. The light emitting layer OL may be formed by, but is not limited to, inkjet printing. The light emitting layers OL may be spaced apart from one another in the emission areas LA1, LA2 and LA3.

The common electrode CE may be disposed on the light emitting layer OL. The common electrode CE may be disposed across the pixels. The common electrode CE may cover the light emitting layers OL and may be disposed on the bank layer 150. The common electrode CE may be in contact with not only the upper surface of the light emitting layer OL and the upper surface of the bank layer 150, but also with the side surfaces of the bank layer 150.

The common electrode CE may include a material layer having a small work function such as Li, Ca, LiF/Ca, LiF/Al, Al, Mg, Ag, Pt, Pd, Ni, Au, Nd, Ir, Cr, BaF and Ba, or a compound or mixture thereof (e.g., a mixture of Ag and Mg). The common electrode CE may further include a transparent metal oxide layer disposed on the material layer having a small work function. The pixel electrodes AE1, AE2 and AE3, the light emitting layer OL and the common electrode CE may form the respective light-emitting elements.

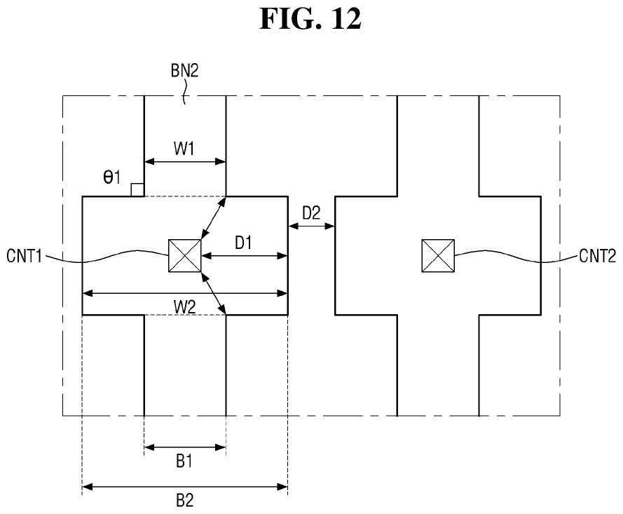

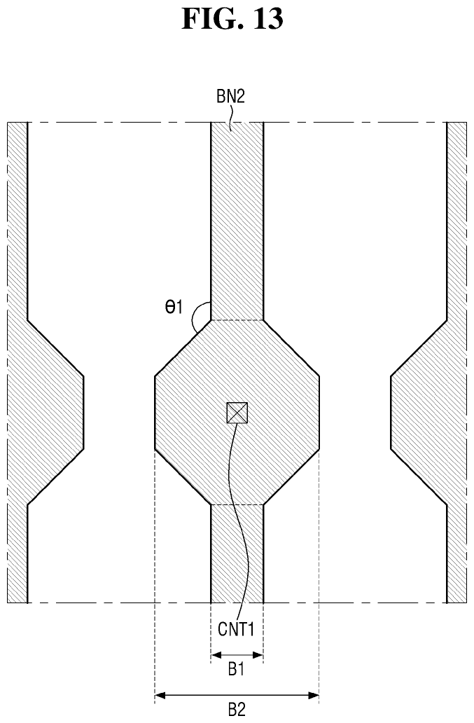

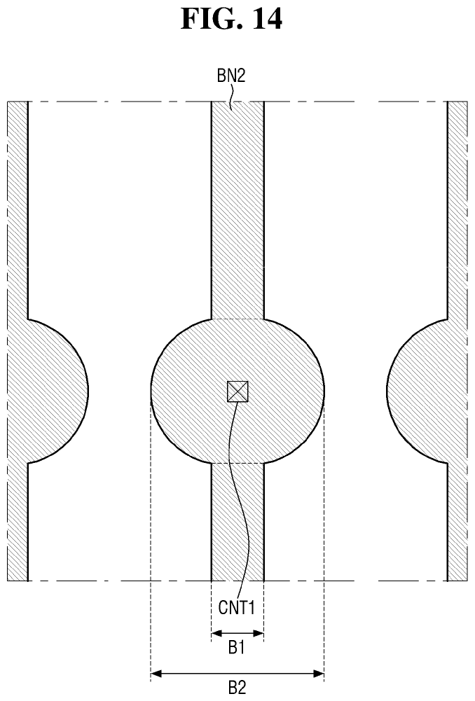

The bank layer 150 will be described with further reference to FIGS. 12 and 14. FIG. 12 is a plan view schematically showing a contact hole and a second bank layer according to an embodiment. FIG. 13 is a plan view schematically showing a contact hole and a second bank layer according to another embodiment. FIG. 14 is a plan view schematically showing a contact hole and a second bank layer according to yet another embodiment.

Referring to FIGS. 12 to 14 in conjunction with FIGS. 6 to 11, the bank layer 150 may include first bank layers BN1 and second bank layers BN2.

The first bank layer BN1 may be disposed on the via layer VIA and the pixel electrodes AE1, AE2 and AE3. The first bank layers BN1 may be extended in the first direction DR1 and may be spaced apart from one another in the second direction DR2. The first bank layers BN1 may separate the emission areas LA1, LA2 and LA3 of the sub-pixel SP1, SP2 and SP3 from one another in the second direction DR2. The first bank layers BN1 may partially cover the pixel electrodes AE1, AE2 and AE3 of the sub-pixels SP1, SP2 and SP3. For example, the first bank layers BN1 may overlap and cover the upper and lower portions of the first pixel electrode AE1 of the first sub-pixel SP1 when viewed from the top. In addition, the first bank layers BN1 may overlap the contact holes CNT1, CNT2 and CNT3 located between the emission areas LA1, LA2 and LA3 of the sub-pixels SP1, SP2 and SP3.

The second bank layers BN2 may be disposed on the via layer VIA, the first bank layers BN1 and the pixel electrodes AE1, AE2 and AE3. The second bank layers BN2 may be extended in the second direction DR2 and may be spaced apart from one another in the first direction DR1. The second bank layers BN2 may cross the first bank layers BN1. The second bank layers BN2 may separate the emission areas LA1, LA2 and LA3 of the sub-pixel SP1, SP2 and SP3 from one another in the first direction DR1. The second bank layers BN2 may partially cover the pixel electrodes AE1, AE2 and AE3 of the sub-pixels SP1, SP2 and SP3. For example, the second bank layers BN2 may overlap and cover the left and right portions of the first pixel electrode AE1 of the first sub-pixel SP1 when viewed from the top. In addition, the second bank layers BN2 may overlap the contact holes CNT1, CNT2 and CNT3 located between the emission areas LA1, LA2 and LA3 of the sub-pixels SP1, SP2 and SP3. In each of the contact holes CNT1, CNT2 and CNT3, the first bank layer BN1 and the second bank layer BN2 may cross and overlap each other.

The first bank layer BN1 and the second bank layer BN2 may include an organic insulating material or an inorganic insulating material. For example, the first bank layer BN1 may include at least one of: a polyimide resin, an acrylic resin, a silicon compound, a polyacrylic resin, etc. According to an embodiment of the present disclosure, the first bank layers BN1 may be made of a transparent insulating material through which light can pass.

The second bank layer BN2 may include a light-blocking material to represent black color. The light-blocking material may include a black pigment. The black pigment may include, for example, at least one selected from the group consisting of: aniline black, perylene black, titanium black, and carbon black. For example, the black pigment may be carbon black. Examples of carbon black may include channel black, furnace black, thermal black, lamp black, etc., and one type or a combination of two or more types may be used. It should be understood, however, that the present disclosure is not limited thereto. The light-blocking material may include an opaque material such as metal particles (e.g., nickel, aluminum, molybdenum and alloys thereof), metal oxide particles (e.g., chromium oxide) and metal nitride particles (e.g., chromium nitride).

As the second bank layers BN2 block light, it is possible to prevent color mixing between adjacent sub-pixels SP1, SP2 and SP3 which may occur if lights reflected off the pixel electrodes AE1, AE2 and AE3 intrude the adjacent sub-pixels SP1, SP2 and SP3. In addition, the second bank layer BN2 can prevent the lights incident from the outside from being reflected off the pixel electrodes AE1, AE2 and AE3. According to the embodiment of the present disclosure, the second bank layers BN2 overlap with the contact holes CNT1, CNT2 and CNT3, so that it is possible to further block the lights reflected off the pixel electrodes AE1, AE2 and AE3 disposed in the contact holes CNT1, CNT2 and CNT3.

According to an embodiment of the present disclosure, the first bank layer BN1 may have lyophilic properties, and the second bank layer BN2 may have lyophobic properties.

As used herein, a lyophobic element repels a solution and does not allow the solution to permeate through. A lyophilic element, on the other hand, has high affinity for a solution. For example, a solution may have a low adhesive force with a lyophobic surface, and the surface tension of the solution located on the lyophobic surface may increase. On the other hand, a solution may have a high adhesive force with a lyophilic surface, and the surface tension of the solution located on the lyophilic surface may decrease.

When a solution is located on a lyophobic surface, the solution may have a contact angle greater than that of the solution located on a lyophilic surface. The contact angle may refer to an angle formed by a tangent line of a solution located on a surface at the contact point and the surface. The contact angle may increase with the lyophobic nature or the surface tension. Although not limited thereto, for example, when water is located on a lyophobic surface, the contact angle of the water on the surface may be greater than 90° and less than 180°. In addition, when water is located on a lyophilic surface, the contact angle of the water on the surface may be greater than 0° and less than 90°.

As will be described later, during the process of fabricating the display device, the light emitting layer may be fabricated via an inkjet printing process in which an ink containing a material for the light emitting layer is sprayed. For example, the ink may be sprayed onto the first sub-pixels SP1 emitting light of the same color extended in the second direction DR2. The ink sprayed onto the first sub-pixels SP1 spreads in the first emission areas LA1 partitioned by the bank layer 150. It is possible to prevent the ink sprayed onto the first emission areas LA1 from flowing over to the adjacent second and third sub-pixels SP2 and SP3 by virtue of the lyophobic second bank layers BN2. The ink spread in each of the first emission areas LA1 may be evenly spread to the adjacent first emission areas LA1 in the second direction DR2 beyond the first bank layers BN1. Since the first bank layers BN1 are lyophilic, the ink can spread evenly over the first bank layers BN1. Accordingly, the ink sprayed onto the first emission areas LA1 may be applied in the first emission areas LA1 at a uniform thickness.

The first bank layers BN1 may have such a small thickness that the ink can flow over them. The second bank layers BN2 may have a large thickness to prevent the ink from overflowing to surrounding sub-pixels. According to an embodiment of the present disclosure, the thickness TT1 of the first bank layer BN1 may be smaller than the thickness TT2 of the second bank layer BN2. In other words, the thickness TT2 of the second bank layer BN2 may be greater than the thickness TT1 of the first bank layer BN1. For example, the thickness of the first bank layer BN1 may be 0.5 μm or less, preferably 0.1 to 0.5 μm. The thickness of the second bank layer BN2 may be 1 μm or more, preferably 1 to 10 μm.

Referring to FIGS. 12 to 14, the bank layer 150 may overlap the contact holes CNT1, CNT2 and CNT3 to cover the contact holes CNT1, CNT2 and CNT3. According to an embodiment of the present disclosure, the second bank layers BP2 may have wider regions to block lights reflected by the pixel electrodes AE1, AE2 and AE3 in the contact holes CNT1, CNT2 and CNT3.

Specifically, a second bank layer BN2 may include first regions B1 and second regions B2. The first regions B1 may extend in the second direction DR2 and may be located between the emission areas LA1, LA2 and LA3. For example, the first regions B1 may be in contact with the sides of the emission areas LA1, LA2 and LA3 that extend in the second direction DR2. The first regions B1 may not overlap with the contact holes CNT1, CNT2 and CNT3. The second regions B2 may be extended in the first direction DR1 and may be located at boundaries of the sub-pixels SP1, SP2 and SP3. For example, in the second regions B2, the boundaries of the sub-pixels SP1, SP2 and SP3 come into contact with each other. The second regions B2 may overlap with the contact holes CNT1, CNT2 and CNT3. The second bank layers BN2 may have a symmetrical structure with respect to the first direction DR1. If the second bank layers BN2 have an asymmetric structure, that may cause differences in viewing angle from different directions. For the viewing angle to be the same from different direction (e.g., left and right side of the image surface), the second bank layers BN2 may have a symmetrical structure with respect to the first direction DR1 for better viewing angle.

According to an embodiment of the present disclosure, the width W1 of the first regions B1 may be smaller than the width W2 of the second regions B2. In other words, the width W2 of the second regions B2 may be greater than the width W1 of the first regions B1. The width W2 of the second regions B2 may be larger than the width W1 of the first regions B1 so that it covers each of the contact holes CNT1, CNT2 and CNT3.

The second regions B2 of the second bank layer BN2 may have a large area taking into account the margins of the contact holes CNT1, CNT2 and CNT3. As shown in FIG. 10, the via layer VIA in which the contact holes CNT1, CNT2 and CNT3 are formed may be made of an organic material, so that side surfaces of the contact holes CNT1, CNT2 and CNT3, i.e., the length of the inclined surfaces, may be long. The second regions B2 of the second bank layer BN2 may have a large area covering the margins of the inclined surfaces of the contact holes CNT1, CNT2 and CNT3. According to an embodiment of the present disclosure, the distance D1 from the first contact hole CNT1 to the edge of the second regions B2 (see FIG. 12) may be equal to or greater than 5 μm.

In addition, the second regions B2 of the second bank layers BN2 may be spaced apart from each other by a predetermined distance. The sprayed ink may move between the second regions B2 of the second bank layers BN2. The distance D2 between the second regions B2 of the second bank layers BN2 may be equal to or greater than 10 μm to allow the ink to flow at a desired rate.

As shown in FIG. 12, an angle θ1 between one side of the first region B1 and one side of the second region B2 in contact with the one side of the first region B1 of the second bank layer BN2 may be equal to 90 degrees. For example, the shape of the second regions B2 of the second bank layers BN2 may be a rectangle when viewed from the top.

As shown in FIG. 13, an angle θ1 between one side of the first region B1 and one side of the second region B2 in contact with the one side of the first region B1 of the second bank layer BN2 may be greater than 90 degrees. For example, the shape of the second regions B2 of the second bank layers BN2 may be an octagon when viewed from the top. It should be understood, however, that the present disclosure is not limited thereto. The shape of the second regions B2 of the second bank layers BN2 when viewed from the top may be a quadrangle, a hexagon, or other polygons. In this instance, the fluidity of ink spreading from the emission areas LA1, LA2 and LA3 to adjacent emission areas LA1, LA2 and LA3 can be improved.

It should be understood, however, that the present disclosure is not limited thereto. As shown in FIG. 14, the shape of the second regions B2 of the second bank layers BN2 can be a circle or an ellipse when viewed from the top.

As described above, by changing the shape of the second regions B2 of the second bank layer BN2 when viewed from the top, it is possible to adjust the rate of the ink spreading between the emission areas LA1, LA2 and LA3.

Hereinafter, a method of fabricating the display device according to the above-described embodiment of the present disclosure will be described.

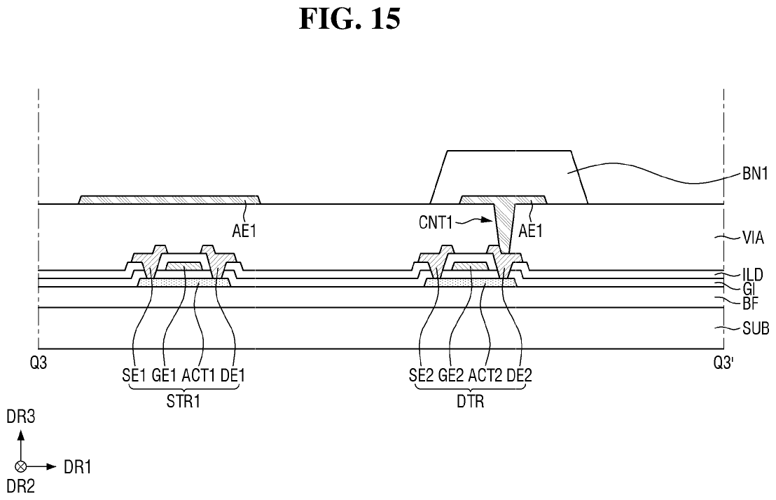

FIGS. 15 to 19 are cross-sectional views showing processing steps of a method of fabricating a display device according to an embodiment of the present disclosure. FIGS. 15 to 19 are cross-sectional views showing processing steps of the structure corresponding to FIG. 11.

Referring to FIGS. 15 to 19, a first bank layer BN1 is formed on the substrate SUB.

Specifically, a switching transistor STR1, a driving transistor DTR, a buffer layer BF, a gate insulator GI, an interlayer dielectric layer ILD, a via layer VIA and a first pixel electrode A1 are formed on the substrate SUB. The above-described elements may be formed by stacking by using physical vapor deposition or chemical vapor deposition and patterning them via a photolithography process. After the switching transistor STR1 and the driving transistor DTR are formed, a via material layer is applied. Then, the via material layer is partially etched to form a contact hole CNT1 exposing the driving transistor DTR, thereby forming the via layer VIA.

The first bank layer BN1 may be formed by applying a first bank material on the first pixel electrode AE1 and the via layer VIA and patterning it via exposure and development processes using a mask. The first bank layer BN1 may be formed to overlap the first contact hole CNT1 through which the driving transistor DTR is connected to the first pixel electrode AE1.

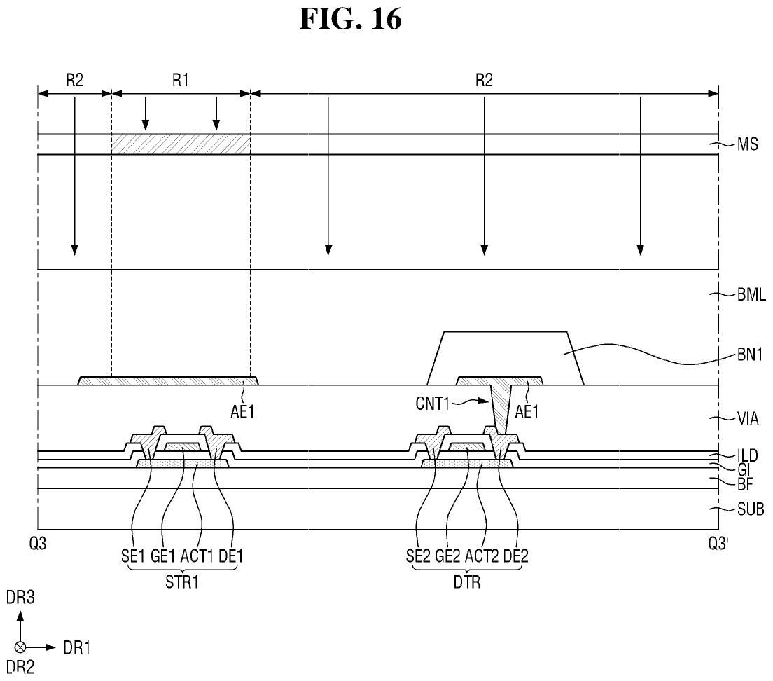

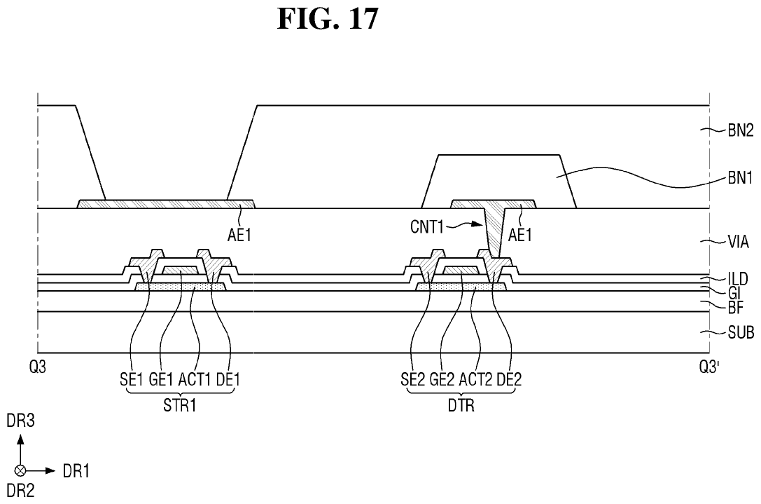

Subsequently, referring to FIGS. 16 and 17, a material for a second bank is applied on the via layer VIA and on the first bank layer BN1 to form a second bank material layer BML. The second bank material layer BML may include a light-blocking material and a fluorine-based compound or a siloxane-based compound capable of exhibiting lyophobic nature.

A mask MS is aligned above the second bank material layer BML. The mask MS may include light-blocking portions R1 and transmissive portions R2 that have different light transmittances. The light-blocking portions R1 can block light to prevent the light from reaching the second bank material layer BML. The transmissive portions R2 may transmit the light so that the light reaches the second bank material layer BML. The light transmittance of the transmissive portions R2 may be greater than the light transmittance of the light-blocking portions R1.

Subsequently, light, for example, ultraviolet (UV) light is irradiated from above the mask MS. Ultraviolet (UV) light are blocked by the light-blocking portion R1 of the mask MS and do not reach the second bank material layer BML in line with the light-blocking portion R1. The ultraviolet (UV) light passes through the transmissive portion R2 of the mask MS and reaches the second bank material layer BML that is aligned with the transmissive portion R2.

In an embodiment, the second bank material layer BML includes a positive photoresist or negative photoresist (sensitizer). When second bank material layer BML includes a positive photoresist, the parts where UV light is blocked by the light-blocking portions R1 remain cured and do not dissolve well in a developing solution. On the other hand, the parts irradiated with UV light through the transmissive portions R2 change the chemical properties and dissolve well in the developing solution. By using a developing solution, it is possible to selectively remove the portions of the second bank material layer BML that are exposed to UV light, leaving the unexposed portions standing, through chemical changes. And when the second bank material layer BML includes a negative photoresist, it may work in the opposite way. For example, the second bank material layer BML includes a negative photoresist, as a result, the portions of the second bank material layer BML aligned with the light-blocking portions R1 of the mask MS are removed, the portions of the second bank material layer BML that are aligned with the transmissive portions R2 of the mask MS are remained. In this embodiment, it is shown as an example that the second bank material layer BML includes a negative photoresist. The resulting second bank layer BN2 is shown in FIG. 17. As a result, the bank layer 150 including the first bank layer BN1 and the second bank layer BN2 may be formed.

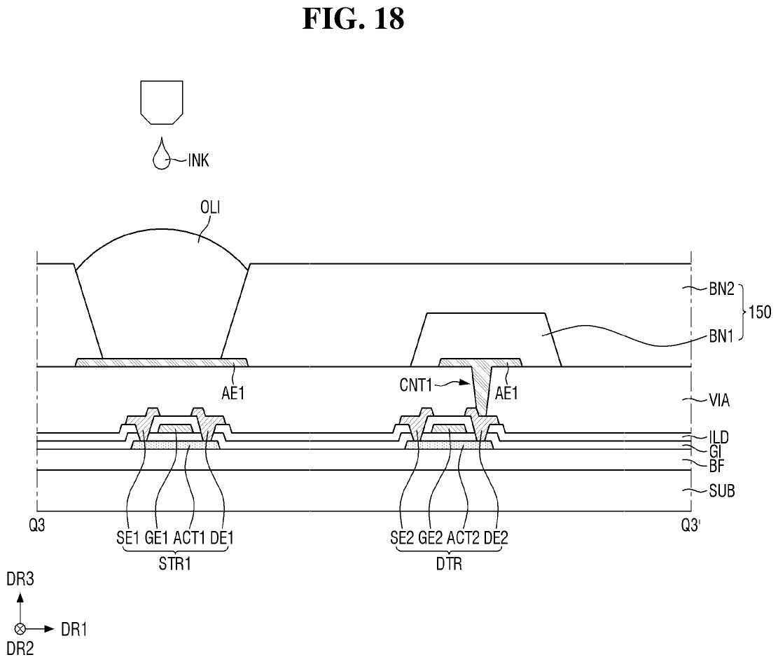

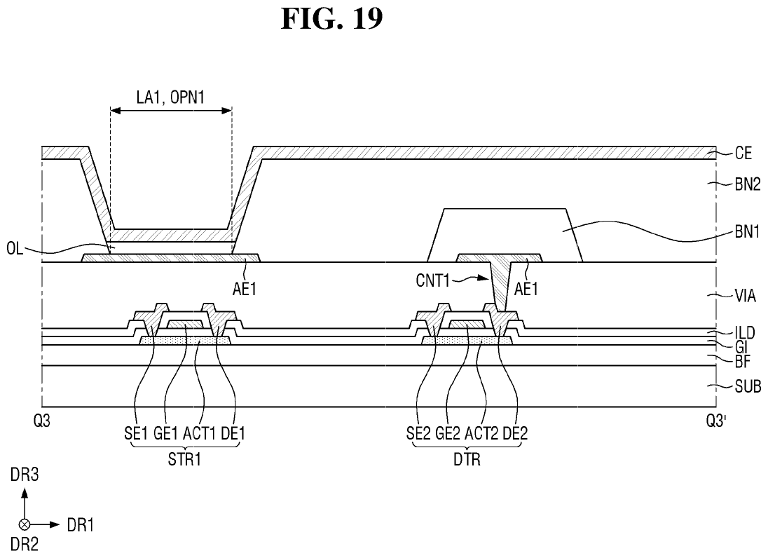

Subsequently, referring to FIGS. 18 and 19, a light emitting layer OL is formed by inkjet printing, and a common electrode CE is formed on the light emitting layer OL and the bank layer 150.

Specifically, a material layer OLI for the light emitting layer is disposed on the first pixel electrode AE1 exposed by the bank layer 150. The second bank layer BN2 of the bank layer 150 has lyophobic nature, leading to a convex meniscus of the material layer OLI on the first pixel electrode AE1. A contact angle between the material layer OLI for the light emitting layer and the second bank layer BN2 may be increased. The material layer OLI for the light emitting layer does not flow over to the lyophobic upper surface of the second bank layer BN2 and can be located more precisely on the first pixel electrode AE1 that is not covered by the second bank layer BN2. Although not shown in the drawings, the material layer OLI for the light emitting layer can evenly spread over the lyophilic first bank layer BN1.

The material layer OLI for the light emitting layer may be sprayed in the form of ink by an inkjet printing device (or a droplet ejection device) and disposed on the first pixel electrodes AE1 that is not covered by the bank layer 150. In this manner, the light emitting layers OL can be more accurately formed at desired positions even in a high-resolution display device.

After inkjet-printing the material layer OLI for the light emitting layer, the material layer OLI is dried to form light emitting layers OL. A drying process evaporates the solvent of the material layer OLI, and the volume can be reduced to form the light emitting layer OL as shown in FIG. 19.

Subsequently, the common electrode CE is formed on the light emitting layer OL and the bank layer 150. The common electrode CE may cover the light emitting layer OL and the bank layer 150.

Hereinafter, other embodiments of the present disclosure will be described. In the following description, the same or similar elements will be denoted by the same or similar reference numerals, and redundant descriptions will be omitted or briefly described. Descriptions will focus on the differences from the above embodiment.

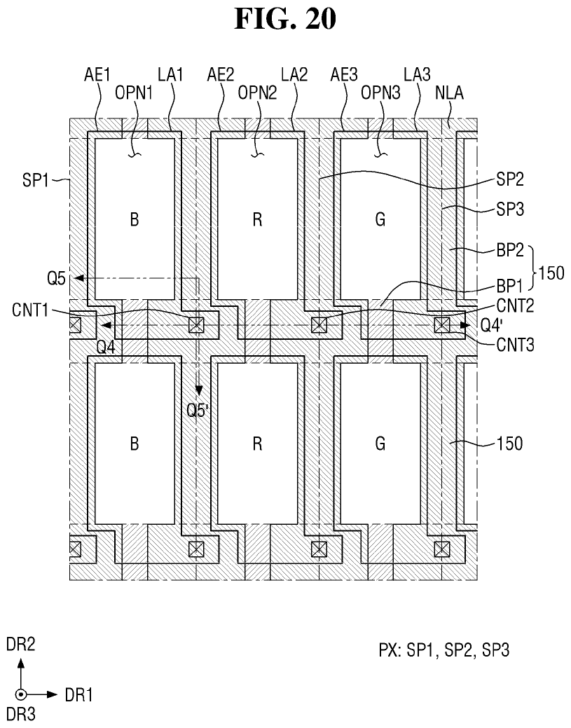

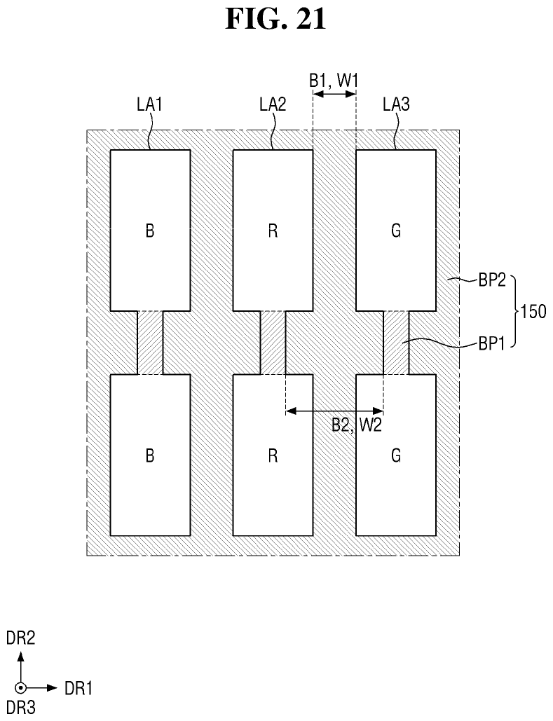

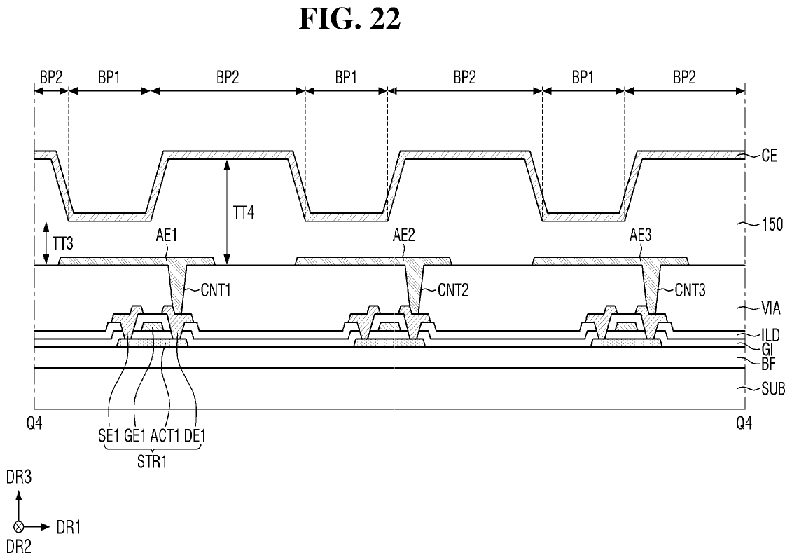

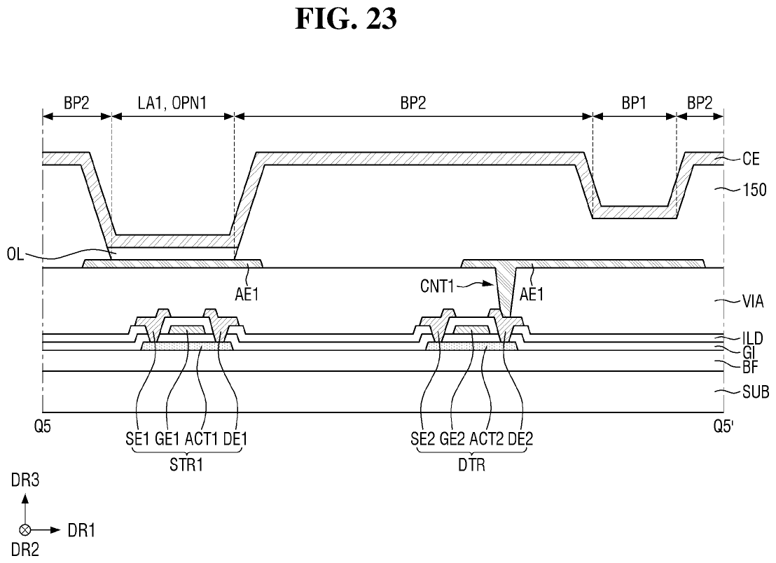

FIG. 20 is a plan view showing a layout of pixels of a display device according to an embodiment of the present disclosure. FIG. 21 is a plan view showing a kb layer of the display device according to the embodiment of the present disclosure. FIG. 22 is a cross-sectional view taken along line Q4-Q4′ of FIG. 20. FIG. 23 is a cross-sectional view taken along line Q5-Q5′ of FIG. 20.

The embodiment of FIGS. 20 to 23 is different from the embodiment of FIGS. 6 to 11 in that a bank layer 150 is made up of a single layer.

Specifically, the bank layer 150 may be made up of a single layer. The bank layer 150 may include, for example, first bank portions BP1 and second bank portions BP2, which are distinguished by thickness. The first bank portions BP1 and the second bank portions BP2 may be integrated as one body.

The first bank portions BP1 may be disposed on the via layer VIA and pixel electrodes AE1, AE2 and AE3. The first bank portions BP1 may be island-shaped portions extending in the second direction DR2. The first bank portions BP1 may be spaced apart from one another in the first and second directions DR1 and DR2. The first bank portions BP1 may be disposed between the emission areas LA1, LA2 and LA3 of the sub-pixel SP1, SP2 and SP3 that are arranged in the second direction DR2. The first bank portions BP1 may partially cover the pixel electrodes AE1, AE2 and AE3 of the sub-pixels SP1, SP2 and SP3. For example, the first bank portion BP1 may overlap and cover the lower portions of the first pixel electrode AE1 of the first sub-pixel SP1 when viewed from the top. In addition, the first bank portions BP1 may not overlap the contact holes CNT1, CNT2 and CNT3 located between the emission areas LA1, LA2 and LA3 of the sub-pixels SP1, SP2 and SP3.

The second bank portions BP2 may be disposed on the via layer VIA, the first bank portions BP1 and the pixel electrodes AE1, AE2 and AE3. The second bank portions BP2 may extend in the second direction DR2 and may be separated from one another in the first direction DR1 due to the presence of the emission areas LA1, LA2, LA3 and the first bank portions BP1, as depicted in FIG. 21. The second bank portions BP2 may separate the emission areas LA1, LA2 and LA3 of the sub-pixel SP1, SP2 and SP3 from one another in the second direction DR2. The second bank portions BP2 may partially cover the pixel electrodes AE1, AE2 and AE3 of the sub-pixels SP1, SP2 and SP3. For example, the second bank portion BP2 may overlap and cover the left, right, upper and lower portions of the first pixel electrode AE1 of the first sub-pixel SP1 when viewed from the top. In addition, the second bank portions BP2 may overlap the contact holes CNT1, CNT2 and CNT3 located between the emission areas LA1, LA2 and LA3 of the sub-pixels SP1, SP2 and SP3.

The first bank portion BP1 and the second bank portion BP2 of the bank layer 150 may include an organic insulating material or an inorganic insulating material, and may include a light-blocking material to represent black color.

As the bank layer 150 blocks light, it is possible to reduce or prevent color mixing between adjacent sub-pixels SP1, SP2 and SP3, which may occur if lights reflected off the pixel electrodes AE1, AE2 and AE3 reach the adjacent sub-pixels SP1, SP2 and SP3. In addition, the bank layer 150 can prevent the lights from the outside from being reflected off the pixel electrodes AE1, AE2 and AE3. According to the embodiment of the present disclosure, the bank layer 150 overlaps the contact holes CNT1, CNT2 and CNT3, so that it is possible to further block the lights reflected off the pixel electrodes AE1, AE2 and AE3 disposed in the contact holes CNT1, CNT2 and CNT3.

According to an embodiment of the present disclosure, the bank layer 150 may have lyophobic nature. Specifically, the first bank portions BP1 and the second bank portions BP2 of the bank layer 150 may have lyophobic nature. As described above, the ink sprayed onto the first sub-pixels SP1 spreads in the first emission areas LA1 partitioned by the bank layer 150. It is possible to prevent the ink sprayed onto the first emission areas LA1 from spilling to the adjacent second and third sub-pixels SP2 and SP3 by making the second bank portions BP2 lyophobic. The ink spread in each of the first emission areas LA1 may be evenly spread to the adjacent first emission areas LA1 in the second direction DR2 beyond the first bank portions BP1. Although the first bank portions BP1 have lyophobic nature, the first bank portions BP1 is shallow in the third direction DR3 and thus the ink can easily spill over. Accordingly, the ink sprayed onto the first emission areas LA1 may be applied in the first emission areas LA1 at a uniform thickness.

The first bank portions BP1 may shallow enough that the ink can spill out of them. The second bank layers BN2 may be thick enough to contain the ink and prevent the ink from spilling onto surrounding sub-pixels. According to an embodiment of the present disclosure, the thickness TT3 of the first bank portions BP1 may be smaller than the thickness TT4 of the second bank portions BP2 (see FIG. 22). The thickness TT4 of the second bank portions BP2 may be greater than the thickness TT3 of the first bank portions BP1. For example, the thickness of the first bank portions BP1 may be equal to or less than 0.5 μm, and the thickness of the second bank portions BP2 may be equal to or more than 1 μm. According to the embodiment of the present disclosure, the second bank portions BP2 with the larger thickness overlap with the contact holes CNT1, CNT2 and CNT3, so that it is possible to effectively block the lights reflected off the pixel electrodes AE1, AE2 and AE3 in the contact holes CNT1, CNT2 and CNT3.

The bank layer 150 may overlap with the contact holes CNT1, CNT2 and CNT3 to cover the contact holes CNT1, CNT2 and CNT3. According to an embodiment of the present disclosure, the second bank portions BP2 may have wider regions to block lights reflected by the pixel electrodes AE1, AE2 and AE3 in the contact holes CNT1, CNT2 and CNT3. The second bank portions BP2 may include first regions B1 and second regions B2 (see FIG. 21). The first regions B1 may not overlap with the contact holes CNT1, CNT2 and CNT3, and the second regions B2 may overlap with the contact holes CNT1, CNT2 and CNT3. According to an embodiment of the present disclosure, the width W1 of the first regions B1 may be smaller than the width W2 of the second regions B2. In other words, the width W2 of the second regions B2 may be greater than the width W1 of the first regions B1. The width W2 of the second regions B2 may be larger than the width W1 of the first regions B1 so that it covers each of the contact holes CNT1, CNT2 and CNT3.

In addition, as shown in FIGS. 12 to 14 described above, the second regions B2 of the second bank portion BP2 of the bank layer 150 may have rectangular, hexagonal, octagonal shapes, etc. when viewed from the top, so that the ink can spread more easily from the emission areas LA1, LA2 and LA3 to the adjacent ones.

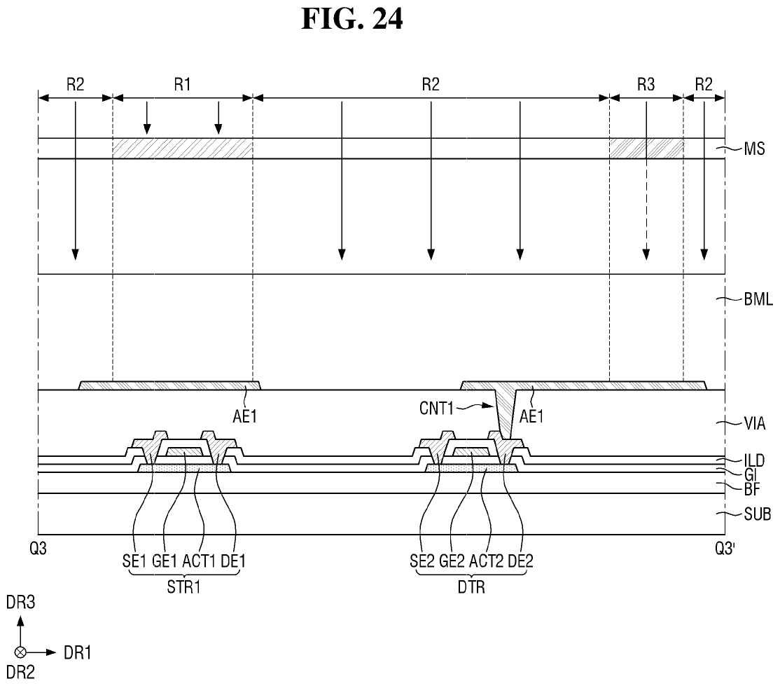

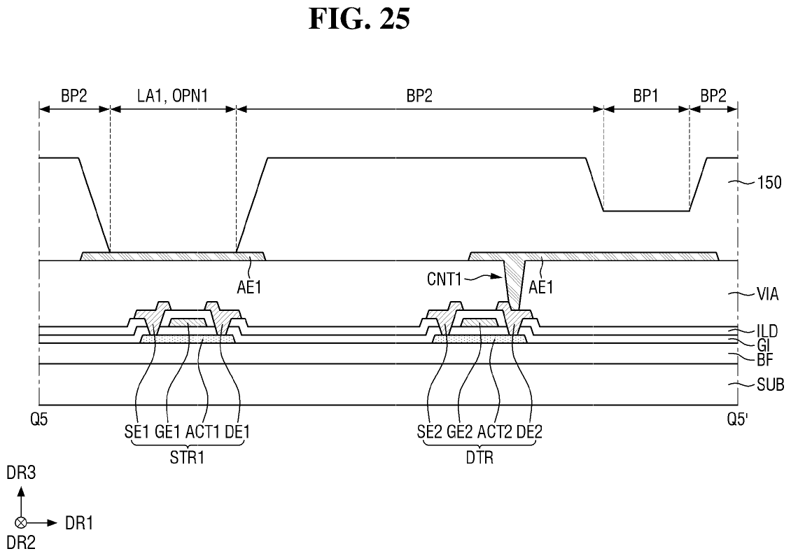

FIGS. 24 and 25 are cross-sectional views showing processing steps of a method of fabricating a display device according to an embodiment of the present disclosure. FIGS. 24 and 25 may correspond to the structure described above with reference to FIG. 23.

Referring to FIGS. 24 and 25, a material for a bank is applied on the substrate SUB where first pixel electrodes AE1 and a via layer VIA are formed, to form a bank material layer BMLL. The bank material layer BMLL may include a light-blocking material and a fluorine-based compound or a siloxane-based compound capable of exhibiting lyophobic nature.

A mask MS is aligned above the bank material layer BMLL. The mask MS may include light-blocking portions R1, transmissive portions R2, and translucent portions R3 having different light transmittances. The light-blocking portions R1 can block light to prevent the light from reaching the bank material layer BMLL. The transmissive portions R2 may transmit the light so that the light reaches the bank material layer BMLL. The translucent portions R3 may partially transmit lights so that only some of the lights reach the bank material layer BMLL. The light transmittance of the transmissive portions R2 may be greater than the light transmittance of the translucent portions R3.

Subsequently, light, for example, ultraviolet (UV) light is irradiated from above the mask MS. Ultraviolet (UV) light is blocked by the light-blocking portions R1 of the mask MS and do not reach the bank material layer BMLL in line with the light-blocking portions R1. The ultraviolet (UV) light passes through the transmissive portions R2 of the mask MS and reaches the bank material layer BMLL in line with the transmissive portions R2. The ultraviolet (UV) light partially passes through the translucent portions R3 of the mask MS and reaches the bank material layer BMLL in line with the translucent portions R3.

In this instance, the portions where UV light is blocked by the light-blocking portions R1 remain cured and dissolve well in the developing solution. The portions irradiated with UV light through the transmissive portions R2 change the chemical properties and do not dissolve well in the developing solution. The portions partially irradiated with UV light through the translucent portions R3 change the chemical properties of the lower part only. Accordingly, the upper part casily dissolves well in the developing solution whereas the lower part does not. At this time, by using the developing solution, it is possible to selectively remove the portions of the bank material layer BMLL that are completely exposed to UV light and the partially exposed portions, leaving the blocked portions due to the chemical changes. As a result, the portions of the bank material layer BMLL aligned with the light-blocking portions R1 of the mask MS are removed, the portions of the bank material layer BMLL in line with the transmissive portions R2 remain, and the portions of the bank material layer BMLL in line with the translucent portions R3 are partially removed, so that the bank layer 150 as shown in FIG. 25 can be formed. Thus, the bank layer 150 including the first bank portions BP1 and the second bank portions BP2 may be formed. Subsequent processes may be performed as described above with reference to FIGS. 15 to 19, to fabricate the display device 10.

As described above, by forming the bank layer 150 including the first bank portions BP1 and the second bank portions BP2 having different thicknesses via a single mask process, it is possible to save the fabrication cost and improve the productivity.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate;
a transistor disposed on the substrate;
a via layer disposed over the transistor and including a contact hole extending to the transistor;
a pixel electrode disposed on the via layer and connected to the transistor through the contact hole;
a first bank layer disposed on the pixel electrode and extending in a first direction, and a second bank layer extending in a second direction crossing the first direction;
a light emitting layer disposed on the pixel electrode; and
a common electrode disposed on the light emitting layer,
wherein the second bank layer comprises a first region that does not overlap the contact hole and a second region that overlaps the contact hole, and
wherein a width of the second region is greater than a width of the first region.

2. The display device of claim 1, wherein the second region of the second bank layer overlaps with the first bank layer.

3. The display device of claim 1, wherein a distance from the contact hole to an edge of the second region is equal to or greater than 5 μm.

4. The display device of claim 1, wherein a thickness of the second bank layer is greater than a thickness of the first bank layer.

5. The display device of claim 1, wherein an angle between one side of the first region and one side of the second region in contact with the one side of the first region is 90 degrees.

6. The display device of claim 1, wherein an angle between one side of the first region and one side of the second region in contact with the one side of the first region is greater than 90 degrees.

7. The display device of claim 1, wherein the second bank layer comprises a light-blocking material.

8. The display device of claim 1, wherein the first bank layer has a thickness of 0.1 to 0.5 μm.

9. The display device of claim 1, wherein the second bank layer has a thickness of 1 to 10 μm.

10. The display device of claim 1, wherein the first bank layer has a water contact angle of greater than zero degrees and less than 90 degrees.

11. The display device of claim 1, wherein the second bank layer has a water contact angle of greater than 90 degrees and less than 180 degrees.

12. A display device comprising:
a substrate;
a transistor disposed on the substrate;
a via layer disposed over the transistor and having a contact hole exposing the transistor;
a pixel electrode disposed on the via layer and connected to the transistor through the contact hole;
a bank layer disposed on the pixel electrode;
a light emitting layer disposed on the pixel electrode; and
a common electrode disposed on the light emitting layer,
wherein the bank layer comprises a first bank portion that does not overlap the contact hole and a second bank portion that overlaps the contact hole, and
wherein a width of the second bank portion is greater than a width of the first bank portion.

13. The display device of claim 12, wherein a thickness of the second bank portion is greater than a thickness of the first bank portion.

14. The display device of claim 12, wherein the bank layer comprises a light-blocking material.

15. The display device of claim 12, wherein the bank layer has a water contact angle of greater than 90 degrees and less than 180 degrees.

16. The display device of claim 12, wherein the first bank portion has a thickness of 0.1 to 0.5 μm.

17. The display device of claim 12, wherein the second bank portion has a thickness of 1 to 10 μm.

18. The display device of claim 12, wherein the first bank portion and the second bank portion are integrated as one body.

19. A method of fabricating a display device, the method comprising:
forming a transistor and a via layer on the substrate;
etching the via layer to form a contact hole exposing the transistor;
forming a pixel electrode connected to the transistor through the contact hole on the via layer;
applying a bank material layer on the pixel electrode and using a mask to form a bank layer comprising a first bank portion that does not overlap the contact hole and a second bank portion that overlaps the contact hole;
forming a light emitting layer on the pixel electrode; and
forming a common electrode on the light emitting layer,
wherein a width of the second bank portion is greater than a width of the first bank portion.

20. The method of claim 19, wherein the mask comprises a light-blocking portion, a transmissive portion and a translucent portion, and
wherein a portion of the bank material layer aligned with the transmissive portion is formed as the second bank portion, while a portion of the bank material layer aligned with the translucent portion is formed as the second bank portion.
